(19) United States
(12) Patent Application Publication
(10) Pub. No.: US 2015/0093287 A1
(43) Pub. Date: Apr. 2, 2015

(54) APPLYING A TITANIUM ALLOY ON A SUBSTRATE

(71) Applicants: Robert Pederson, Vanersborg (SE); Frank Skystedt, Vanersborg (SE)

(72) Inventors: Robert Pederson, Vanersborg (SE); Frank Skystedt, Vanersborg (SE)

(73) Assignee: GKN Aerospace Sweden AB, Trollhattan (SE)

(21) Appl. No.: 14/399,559

(22) PCT Filed: May 16, 2012
(86) PCT No.: PCT/SE2012/000076

§ 371 Date: Dec. 5, 2014

(51) Int. Cl. C22C 14/00; F01D 25/00; B23K 15/00; B23K 9/04; C23C 14/14; C23C 16/06

(52) U.S. Cl. CPC C22C 14/00; C23C 14/14; C23C 16/06; B23K 15/0086; B23K 9/04; F01D 25/005
USPC 420/417; 427/597; 427/250; 219/76.14; 219/74; 219/75; 204/192.1

(57) ABSTRACT

A a titanium alloy can be applied on a substrate by one of melting, welding, and depositing said titanium alloy on said substrate and solidifying said deposited or molten titanium alloy. Further, 0.01-0.4 weight % Boron can be added to said titanium alloy before or during said melting, welding or depositing said titanium alloy on said substrate.

### CROSS REFERENCE TO RELATED APPLICATIONS

This application is a National Phase of, and claims priority to, International Application No. PCT/SE2012/000076, filed on May 16, 2012, of which application is hereby incorporated by reference in its entirety.

### BACKGROUND

Welding or Metal Deposition are methods used to manufacture new components, to add material to existing components, to repair components that have been damaged during their manufacture, for example to repair defects arising during a molding process or caused by incorrect machining, and to repair components that have been damaged during their use.

Welding or Metal Deposition may be used to manufacture a component or to apply a metal coating which has increased resistance to oxidation, corrosion, particle erosion, heat and/or wear. If such a component or metal coating is used in an aggressive environment, such as that encountered in a gas turbine engine, where components can be exposed to an oxidizing atmosphere and temperatures over 800° C. for prolonged amounts of time, the component/metal coating can become brittle over time or crack due to thermal cycling and metal fatigue, occurring when the turbine engine is taken in and out of service, for example.

Titanium alloys are used for a wide variety of aerospace applications because of their high specific strength at elevated temperatures, excellent corrosion and oxidation resistance and good creep resistance. Ti-6A1-4V is used for most aerospace and propulsion systems. However, deposited Ti-6A1-4V material has a coarse grain size, typically of the order of several millimeters, which adversely affects the mechanical properties of the deposited Ti-6A1-4V material.

U.S. Pat. No. 7,521,017 concerns reinforced metal matrix composites and methods of shaping powder materials to form such composites. Articles of manufacture are formed in layers by a laser fabrication process. In the process, powder is melted and cooled to form successive layers of a discontinuously reinforced metal matrix. The matrix exhibits a fine grain structure with enhanced properties over the unreinforced metal, including higher tensile modulus, higher strength, and greater hardness. An in-situ alloy powder, a powder metallurgy blend, or independently provided powders are reinforced with 0-35 weight %, more preferably about 0.5 to 10 weight % of Boron, and/or 0-20 weight % carbon, more preferably about 0.5 to 5 weight % of carbon, to form the composite.

In aerospace applications it is however advantageous to apply material having the properties of a metal, rather than the properties of a composite, since a composite material is less ductile than a metal, for example.

### SUMMARY

The present disclosure concerns a method for applying a titanium alloy on a substrate by welding, melting or metal deposition, and also a component comprising a titanium alloy applied using such a method. Further disclosed is a gas turbine engine comprising at least one such component. Yet further disclosed is use of said titanium alloy and a filler material comprising said titanium alloy.

Accordingly, this disclosure includes an improved method for applying a titanium alloy on a substrate. The method comprises the step of melting, welding or depositing the titanium alloy on a substrate, and solidifying the deposited, welded or molten titanium alloy. The method also comprises the step of adding 0.01-0.4 weight % Boron to the titanium alloy before or during the step of melting, welding or depositing the titanium alloy on a substrate.

It has been found that the addition of 0.01-0.4 weight % Boron to a titanium alloy substantially reduces the grain size of the titanium alloy, as compared to the grain size of the grains of a titanium alloy not containing Boron. The grain size here refers to the beta grain size and the size of these grains can be several milimeters in length. It has also been found that the smaller grain size achieved by adding Boron to a titanium alloy improves the strength, hardness and Young's Modulus, as compared to the strength, hardness and Young's Modulus of a titanium alloy not containing Boron. Welding and metal deposition namely involves melting a material followed by solidification during which small Ti2B particles will form and inhibit grain growth during cooling.

The solubility of Boron in titanium alloys is very limited. For example the solubility limit is less than 0.04 wt % Boron in the titanium alloy Ti-6A1-4V. This means that during solidification, excessive Boron (the amount of Boron that cannot dissolve in titanium) will precipitate heterogeneously in the beta grain boundaries and inhibit further grain growth of the beta grains during further cooling. The Boron precipitates themselves are brittle in nature and will degrade the fracture toughness and the ductility of the materials when the amount of these precipitates exceeds a critical amount, which would be detrimental to any aerospace engine application. However, as long as the amount of these Ti₂B-precipitates is small enough, as found in cast Ti-6A1-4V with additions of up to 0.4 wt % Boron by the inventors, the fracture toughness and ductility of the metallic materials is not degraded and significant grain refinement is still achieved with improved strength, hardness and Young's Modulus. As disclosed herein, it is believed that if a small amount of Boron, namely 0.01-0.4 weight % Boron, is added to a welded or deposited titanium alloy, titanium boride particles (TiB-particles) are heterogeneously distributed along the grain boundaries of the titanium alloy after solidification, which results in a significantly reduced grain size and thus improved mechanical properties as compared with a molten, welded or deposited titanium alloy not containing Boron.

The word “substrate” may mean any substratum that supports the applied titanium alloy. The substrate need not necessarily be an underlying support, but may for example be arranged to support molten, welded or deposited material in any suitable manner. The substrate may be of any suitable material, shape or size. The substrate may be an at least partly solidified titanium alloy onto which more titanium alloy is applied. A substrate may be formed of one or more constituent parts. At least one substrate and the applied titanium alloy may be arranged to form a unitary component. For example, a substrate may be a component on which titanium alloy is applied by melting, welding or metal deposition, whereby the applied titanium alloy then constitutes part of that component or fusion zone that may be used to join that component to another component.

According to an embodiment, the method comprises the step of adding 0.01-0.2 weight % Boron or 0.01-0.1 weight % Boron to the titanium alloy before or during the step of melting or depositing the titanium alloy on a substrate .

According to an embodiment, the step of melting, welding or depositing the titanium alloy on a substrate comprises the step of heating a powder or a wire comprising the titanium alloy and the 0.01-0.4 weight % Boron.

According to another embodiment, the titanium alloy is one of ASTM (American Society for Testing and Materials) Grade 5-Grade 38 titanium alloy, e.g., ASTM Grade 6-Grade 38 titanium alloy. The ASTM defines a number of alloy standards with a numbering scheme for easy reference. According to one embodiment, the titanium alloy is one of the following: Ti-6A1-4V (which is also known as ASTM Grade 5, or T1 6-4), Ti-6A1-2Sn-4Zr-2Mo. It should however be noted that the presently-disclosed method may be used with any titanium alloy.

Ti-6A1-4V is significantly stronger than commercially pure titanium while having the same stiffness and thermal properties. Among its many advantages, it is heat treatable and has an excellent combination of strength, corrosion resistance, weld and fabricability. Consequently, it is used extensively in Aerospace, Medical, Marine, and Chemical Processing applications.

According to a further embodiment, the step of melting, welding or depositing the titanium alloy on a substrate is carried out using any one of: Laser Metal Deposition (LMD), Laser welding, Electron Beam Melting, Shaped Metal Deposition (SMD), Tungsten Inert Gas (TIG) melting, Metal Inert Gas (MIG) melting, filament evaporation, electron beam evaporation, and sputter deposition. It should however be noted that the method may involve applying titanium alloy using any suitable method.

According to an embodiment, the titanium alloy is applied on said substrate so that it forms a layer on said substrate. According to another embodiment, the substrate comprises two parts and that said titanium alloy is applied so that said two parts are joined.

It should be noted that the expression “layer,” as used in this document, is intended to mean a stratum or fusion zone that continuously or non-continuously covers at least part of the substrate on which it is molten, welded or deposited. A fusion zone may be used to join one or more components or component parts together. The layer can be of any uniform or non-uniform thickness, shape, size and/or cross-sectional area. According to an embodiment, the layer has a maximum thickness of 3 mm, 2 mm or 1 mm By applying consecutive layers, a desired shape can be produced. In one application a total thickness of the deposited material (several layers) is about 20 mm.

According to an embodiment, the titanium alloy is applied via energy supply in the form of local heating of the substrate material to the melting temperature of the titanium alloy, via plastic local floating or via atomic diffusion.

The present disclosure also concerns a component that comprises titanium alloy applied using a method according to any embodiments arising from this disclosure. The component may namely comprise applied titanium alloy on a surface thereof or it may be at least partly constituted of the applied titanium alloy.

Also disclosed is a gas turbine engine that comprises at least one component according to any of the embodiments of the invention.

Further disclosed is the use of a titanium alloy comprising 0.01-0.415 weight % Boron for melting, welding or depositing material on a substrate.

Also disclosed is a filler material in the form of powder or wire of a titanium alloy for melting, welding or depositing on a substrate, whereby the titanium alloy comprises 0.01-0.4 weight % Boron.

### BRIEF DESCRIPTION OF THE DRAWINGS

Various embodiments will hereinafter be further explained according to non-limiting examples with reference to the appended figures where;

FIG. 1 is a schematic longitudinal sectional view illustration of an exemplary embodiment of a gas turbine engine,

FIG. 2 is a schematic view of a method according to an embodiment,

FIG. 3 is a graph showing the effect of weight-% Boron on the grain size of a titanium alloy,

FIG. 4 shows the microstructure in a cross section of a titanium alloy applied using a method according to an embodiment,

FIG. 5 shows micrographs showing the microstructure of a titanium alloy applied using a method according to an embodiment, and

FIG. 6 is a flow chart showing the steps of a method according to an embodiment.

It should be noted that the drawings have not been drawn to scale and that the dimensions of certain features may have been exaggerated for the sake of clarity.

### DETAILED DESCRIPTION OF EXEMPLARY EMBODIMENTS

Exemplary embodiments are discussed below. It is to be understood, however, that the embodiments are included in order to explain principles of the invention and not to limit the scope of the invention defined by the appended claims. It should also be noted that any feature of the invention that is disclosed with respect to a particular embodiment of the invention may be incorporated into any other embodiment of the invention.

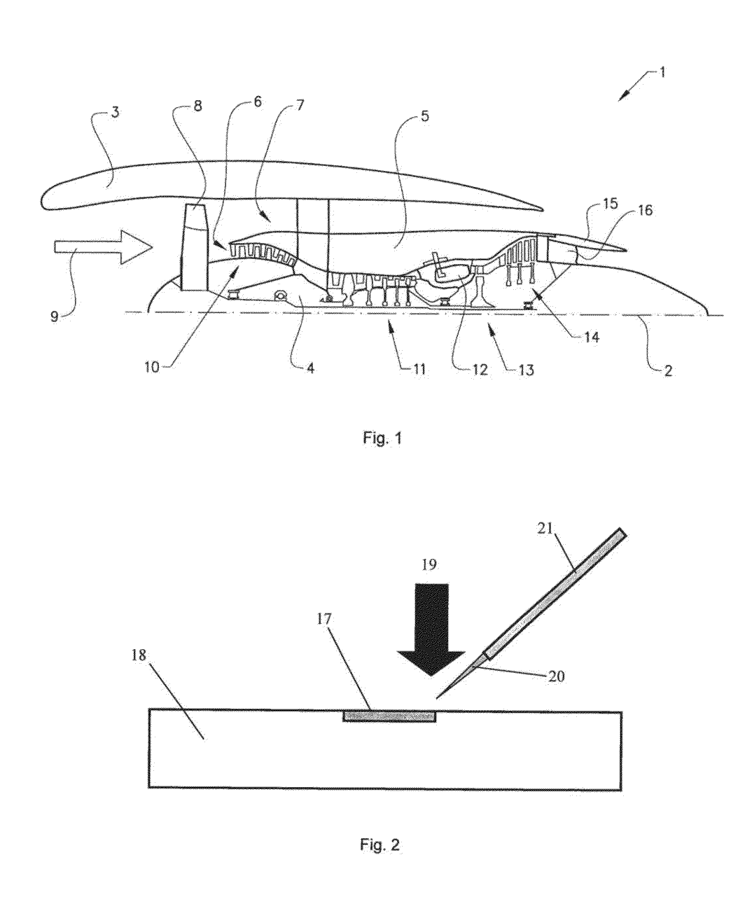

FIG. 1 illustrates a two-shaft turbofan gas turbine aircraft engine 1, which is circumscribed about an engine longitudinal central axis 2. The engine 1 comprises an outer casing or nacelle 3, an inner casing 4 (rotor) and an intermediate casing 5. The intermediate casing 5 is concentric to the first two casings and divides the gap between them into an inner primary gas channel 6 for the compression of air and a secondary channel 7 through which the engine bypass air flows. Thus, each of the gas channels 6, 7 is annular in a cross section perpendicular to the engine longitudinal central axis 2.

The gas turbine engine 1 comprises a fan 8 which receives ambient air 9, a booster or low pressure compressor (LPC) 10, and a high pressure compressor (HPC) 11 arranged in the primary gas channel 6, a combustor 12 which mixes fuel with the air pressurized by the high pressure compressor 11 for generating combustion gases which flow downstream through a high pressure turbine (HPT) 13, and a low pressure turbine (LPT) 14 from which the combustion gases are discharged from the engine.

A high pressure shaft joins the high pressure turbine 13 to the high pressure compressor 11 to substantially form a high pressure rotor. A low pressure shaft joins the low pressure turbine 14 to the low pressure compressor 10 to substantially form a low pressure rotor. The low pressure shaft is at least in part rotatably disposed co-axially with, and radially inwardly of, the high pressure rotor.

The gas turbine engine 1 further comprises a turbine exhaust casing 15 located downstream of the high pressure turbine 13. The turbine exhaust casing 15 comprises a support structure 16.

At least one of the components of a gas turbine engine 1, such as that shown in FIG. 1 10 may comprise at a titanium alloy applied using a method according to any embodiment.

FIG. 2 schematically shows a method for applying a titanium alloy, ASTM Grade 5-Grade 38 titanium alloy, such as Ti-6A1-4V, Ti-6A1-2Sn-4Zr-2Mo, on a substrate 18 by metal deposition, welding or melting. The titanium alloy may comprise 1-8 wt % aluminum, especially 3-7 wt % aluminum and advantageously 5,50-6,75 wt % aluminum. The titanium alloy preferably comprises 1-10 wt % vanadium, preferably 2-8 wt % vanadium and advantageously 3,5-4,5 wt % vanadium.

Ti-6A1-4V has a chemical composition of 6 wt % aluminum, 4 wt % vanadium, 0.25 wt % (maximum) iron, 0.2 wt % (maximum) oxygen, and the remainder titanium.

According to a further example, a method may include applying a titanium alloy in the form of Ti-64. Ti-64 comprises:

Aluminum: 5.50-6.75 wt %;

Vanadium: 3.50-4.50 wt %;

Iron: 0-0.30 wt %;

Oxygen: 0-0.20 wt %;

Carbon: 0-0.08 wt %;

Nitrogen: 0-0.05 wt % (500 ppm);

Hydrogen: 0-0.125 wt % (125 ppm); Yttrium: 0-0.005 wt % (50 ppm); Titanium remainder.

According to a further example, a method may include applying a titanium alloy in the form of Ti-6242. Ti-6242 comprises:

Aluminum: 5.50-6.50 wt %;

Vanadium: 3.60-4.40 wt %;

Molybdenum: 1.80-2.20 wt %;

Tin: 1.80-2.20 wt %;

Silicon: 0.06-0.10 wt %; Oxygen: 0-0.15 wt %;

Iron: 0-0.10 wt %;

Carbon: 0-0.05 wt %;

Nitrogen: 0-0.05 wt % (500 ppm);

Hydrogen: 0-0.125 wt % (125 ppm); Yttrium: 0-0.005 wt % (50 ppm); Titanium remainder.

The method comprises the step of using an energy source 19 to heat powder or a wire 20 comprising the titanium alloy and 0.01-0.4 weight % Boron, which powder or wire 20 may supplied to the substrate 18 using a powder/wire feeder 21. In the illustrated embodiment, the method is used to add material to an existing component (substrate 18), for example to repair a component that has been damaged during its manufacture, for example due to a defect arising during a molding process or caused by incorrect machining, or to repair a component that has been damaged during its use.

The 0.01-0.4 weight % Boron may be added to a titanium alloy, for example in the form of powder or a wire before or during the step of melting or depositing the titanium alloy on a substrate 18.

The titanium alloy may be melted, welded or deposited on a substrate using any one of: Laser Metal Deposition (LMD}, Electron Beam Melting, Shaped Metal Deposition (SMD), Tungsten Inert Gas {TIG) melting, Metal Inert Gas (MIG) melting, filament evaporation, electron beam evaporation, sputter deposition or any other suitable method.

The titanium alloy may be applied via energy supply in the form of local heating of the substrate material to the melting temperature of the titanium alloy, via plastic local floating or via atomic diffusion.

The layer 17 applied titanium alloy has a maximum thickness of 3 mm. It should be noted that the layer 17 need not necessarily have a uniform thickness.

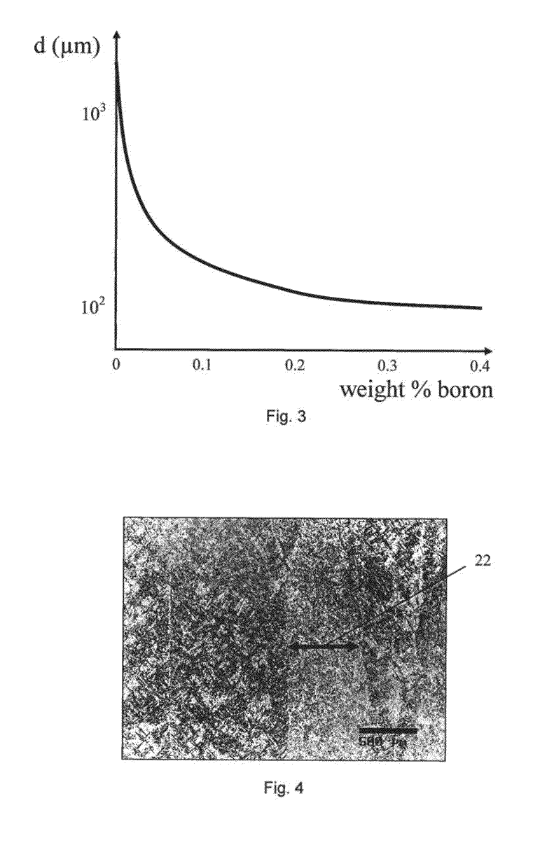

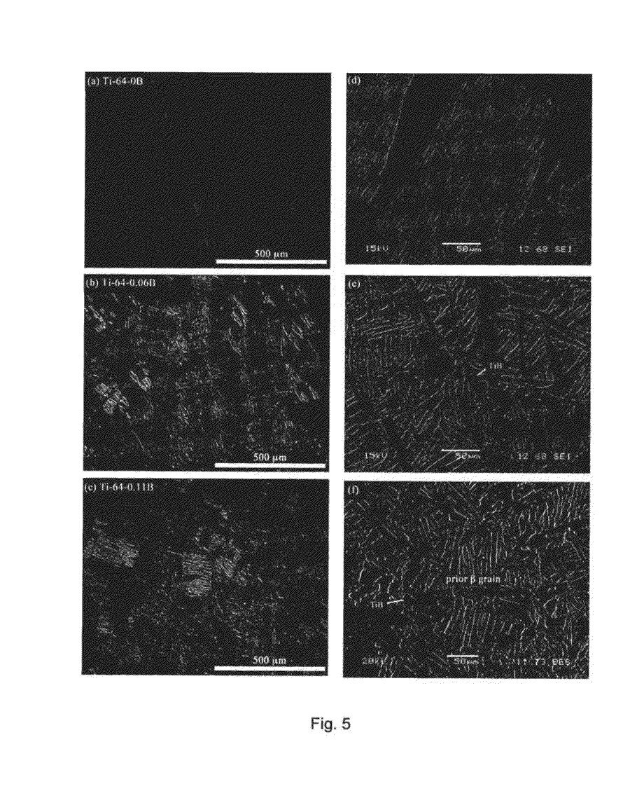

FIG. 3 is a graph showing the effect of weight-% Boron on the beta grain size of a cast titanium alloy. It can be seen that the addition of 0.01-0.4 weight % Boron to a titanium alloy substantially reduces the prior beta grain size of the cast titanium alloy, as compared to the grain size of cast titanium alloy not containing Boron. It has also been found that a disclosed method improves the strength, hardness and Young's Modulus of cast titanium alloy as compared to the strength, hardness and Young's Modulus of a cast titanium alloy not containing Boron.

FIG. 4 shows the microstructure in a cross section of several layers of a titanium alloy formed using a method according to an embodiment. The titanium alloy layers exhibits a microstructure containing prior beta grains (the prior beta grain size=the length of the arrow 22 shown in FIG. 4) which can have a maximum grain size (length of arrow 22) of several millimetres in titanium alloys with no Boron addition. This maximum grain size is significantly reduced by adding 0.01-0.4 wt % Boron to a molten, welded or deposited titanium alloy. The maximum grain size may be measured using an optical microscope.

Figures S(a) and S(d) are micrographs of cast Ti-64 with no Boron addition. Figures S(b) and S(e) are micrographs of cast Ti-64 with 0.06 wt % Boron. Figures S(c) and S(f) are micrographs of cast Ti-64 with 0.11 wt % Boron. Titanium boride (TiB) particles are heterogeneously distributed along the grain boundaries of a cast titanium alloy after solidification (see figures e and f}, which results in a significantly reduced grain size compared to the prior beta grain size of figures a, b and c) and thus improved mechanical properties as compared with a cast titanium alloy not containing Boron.

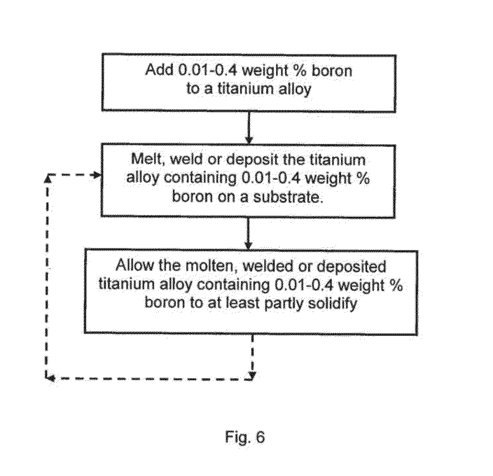

FIG. 6 is a flow chart showing the steps of a method according to an embodiment. The method comprises the steps of adding 0.01-0.4 weight % Boron to a titanium alloy, for example by alloying a titanium alloy powder or wire with Boron, melting, welding or depositing the titanium alloy containing 0.01-0.4 weight % Boron on a substrate using any suitable metal deposition method, and allowing the titanium alloy containing 0.01-0.4 weight % Boron to at least partly solidify. Optionally, additional titanium alloy material may be melted or deposited on the at least partly solidified titanium alloy containing 0.01-0.4 weight % Boron.

Further modifications of the invention within the scope of the claims would be apparent to a skilled person.

1-26. (canceled)

27. A method of applying a titanium alloy on a substrate, comprising:
performing one of melting, welding, and depositing of said titanium alloy on said substrate; and
adding 0.01-0.4 weight % Boron to said titanium alloy at one of before and during said step of melting, welding or depositing said titanium alloy on said substrate, to solidify said titanium alloy.

28. The method of claim 27, wherein performing the one of the melting, welding, and depositing of said titanium alloy on said substrate comprises heating one of a powder and a wire comprising said titanium alloy and said 0.01-0.4 weight % Boron.

29. The method of claim 27, wherein said titanium alloy is one of American Society for Testing and Materials (ASTM) Grade 5-Grade 38 titanium alloy.

30. The method of claim 27, wherein said titanium alloy is one of the following: Ti-6A1-4V and Ti-6A1-2Sn-4Zr-2Mo.

31. The method of claim 27, wherein performing the one of the melting, welding, and depositing of said titanium alloy on said substrate or a weld joint is carried out using any one of: Laser Metal Deposition (LMD), Laser welding Electron Beam Melting (EMB), Shaped Metal Deposition (SMD), Tungsten Inert Gas (TIG) melting, Metal Inert Gas (MIG) melting, filament evaporation, electron beam evaporation, and sputter deposition.

32. The method of claim 27, wherein said titanium alloy is applied on said substrate so that it forms a layer on said substrate.

33. The method of claim 32, wherein said layer has a maximum thickness of 3 millimeters.

34. The method of claim 27, wherein said substrate comprises two parts and said titanium alloy is applied so that said two parts are joined.

35. The method of claim 27, wherein said titanium alloy is applied via an energy supply in the form of local heating of the substrate material to the melting temperature of said titanium alloy, via one of plastic local floating and via atomic diffusion.

36. A component, comprising a titanium alloy, the titanium allow applied by:
performing one of melting, welding, and depositing of said titanium alloy on said substrate; and
adding 0.01-0.4 weight % Boron to said titanium alloy at one of before and during said step of melting, welding or depositing said titanium alloy on said substrate, to solidify said titanium alloy.

37. A gas turbine engine comprising at least one component, the at least one component comprising a titanium alloy, the titanium allow applied by:
performing one of melting, welding, and depositing of said titanium alloy on said substrate; and
adding 0.01-0.4 weight % Boron to said titanium alloy at one of before and during said step of melting, welding or depositing said titanium alloy on said substrate, to solidify said titanium alloy.
